(19) United States
(12) Patent Application Publication
(10) Pub. No.: US 2012/0193746 A1
(43) Pub. Date: Aug. 2, 2012

(54) SEMICONDUCTOR CHIP AND MULTI-CHIP PACKAGE HAVING THE SAME

(75) Inventor: Ji Tai SEO, Icheon-si (KR)

(73) Assignee: HYNIX SEMICONDUCTOR INC., Icheon-si (KR)

(21) Appl. No.: 13/219,631

(22) Filed: Aug. 27, 2011

(30) Foreign Application Priority Data
Jan. 31, 2011 (KR) 10-2011-0009802

(51) Int. Cl. H01L 23/538

(52) U.S. Cl. 257/476; 257/777; 257/E23.174; 257/E23.002

(57) ABSTRACT

A semiconductor chip includes: a semiconductor substrate; an interface member formed through the semiconductor substrate and electrically coupled to an external signal transfer terminal; and a backward diode formed between the semiconductor substrate and the interface member.

### CROSS-REFERENCES TO RELATED APPLICATION

The present application claims priority under 35 U.S.C. §119(a) to Korean application number 10-2011-0009802, filed on Jan. 31, 2011, in the Korean Intellectual Property Office, which is incorporated herein by reference in its entirety.

### BACKGROUND

1. Technical Field

The present invention relates generally to a semiconductor apparatus, and more particularly, to a semiconductor chip including a through silicon via (TSV) and a multi-chip package having the same.

2. Related Art

The semiconductor memories used in most modern electronic systems have larger memory capacity and higher operating speed than those of the past. Further, to mount a larger capacity memory inside a smaller area and to effectively drive the mounted memory has been a research focus.

To achieve a higher level of integration, the three-dimensional arrangement techniques involving vertical stacking of memory chips were utilized in the semiconductor memory design, instead of the two-dimensional arrangements.

The concept of three-dimensional arrangement is also applied to the semiconductor packaging design. For example, the through silicon via (TSV) techniques, which form TSVs through the stacked chips for an interface between the stacked chips, became one area of research interest.

In general, a TSV refers to a via hole formed through a semiconductor chip and filled with a conductive material. To prevent a short between the semiconductor and the TSV, a rounding oxide is formed therebetween the semiconductor chip and the TSV.

However, because of the rounding oxide in between the TSV and the semiconductor chip, the undesirable parasitic capacitance develops around the TSV, which reduces the TSV signal transmission speed.

### SUMMARY

In an embodiment of the present invention, a semiconductor chip includes: a semiconductor substrate; an interface member formed through the semiconductor substrate and electrically coupled to an external signal transfer terminal; and a backward diode formed between the semiconductor substrate and the interface member.

In an embodiment of the present invention, a multi-chip package includes: a plurality of stacked semiconductor chips; a plurality of interface members formed through the respective semiconductor chips to electrically couple the semiconductor chips; and a plurality of external coupling terminals provided to electrically couple the interface members inside the plurality of stacked semiconductor chips. The plurality of interface members built in the semiconductor chips are directly contacted.

In an embodiment of the present invention, a multi-chip package includes: a plurality of stacked semiconductor chips; a plurality of interface members formed through the respective semiconductor chips to electrically couple the semiconductor chips; a plurality of external coupling terminals provided to electrically couple the interface members inside the plurality of stacked semiconductor chips; and a plurality of wells surrounding the respective interface member and having an opposite conductive type to that of the semiconductor chips.

### BRIEF DESCRIPTION OF THE DRAWINGS

Features, aspects, and embodiments are described in conjunction with the attached drawings, in which:

FIG. 1 is a plan view of a semiconductor chip according to an embodiment of the present invention;

FIG. 2 is a cross-sectional view taken along a line II-II′ of FIG. 1;

FIG. 3 is a diagram showing voltages provided to a semiconductor substrate and an interface member according to an embodiment of the present invention;

FIG. 4 is a cross-sectional view of a multi-chip package according to an embodiment of the present invention;

FIG. 5 is a plan view of a semiconductor chip according to an embodiment of the present invention;

FIG. 6 is a cross-sectional view taken along a line VI-VI′ line of FIG. 5; and

FIG. 7 is a cross-sectional view of a semiconductor chip according to an embodiment of the present invention.

### DETAILED DESCRIPTION

Hereinafter, a semiconductor chip and a multi-chip package according to the present invention will be described below with reference to the accompanying drawings through exemplary embodiments.

In exemplary embodiments of the present invention, an interconnection may refer to a conductor formed generally along a horizontal direction to conduct electrical signal, and a via may refer to a conductor formed generally along a vertical direction to conduct electrical signal. Regardless of the way they are illustrated in the drawings, interconnections may be extended generally along a horizontal direction, and the vias may be extended generally along a vertical direction. The A via includes a plug and a hole, among others. A via plug refers to a pillar-shaped conductor filled inside the via hole, and a via hole refers to hollow structures, in which a via plug may be found.

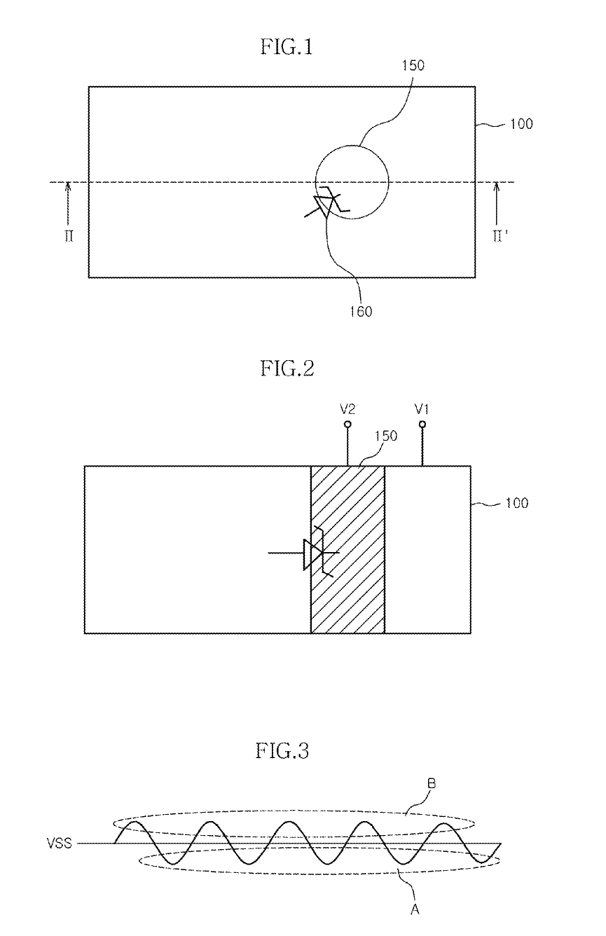

FIG. 1 is a plan view of a semiconductor chip according to an embodiment of the present invention. FIG. 2 is a cross-sectional view taken along a line II-II′ of FIG. 1.

Referring to FIGS. 1 and 2, the semiconductor chip includes a semiconductor substrate 100 and an interface member 150 formed through the semiconductor chip 100.

The semiconductor substrate 100 may include a silicon chip structure in which a circuit layer, a metal interconnection layer, and a protective layer, among others, are formed. The circuit layer may include a layer which contains semiconductor circuits for a variety of electrical operations. The metal interconnection layer may include a layer which delivers electrical signals to the circuit layer from outside or to the outside from the circuit layer. The protective layer may have a multilayer structure which is formed by using a variety of insulation materials such as silicon oxide, silicon nitride, silicon oxynitride, and polyimide.

The interface member 150 may include a through-via and a via plug buried in the through-via (hereinafter, collectively referred to as a TSV). The TSV 150 may include, for example, copper (Cu) or aluminum (Al) and may be formed through the circuit layer, the metal interconnection layer, and the protection layer as well as the semiconductor substrate. Although not shown in the drawings, a metal layer may be interposed between the semiconductor substrate 100 and the TSV 150, in order to improve the adhesive force therebetween.

In an embodiment, when forming conductive patterns of Cu or by performing a plating technique, a seed layer would be formed prior to performing a plating process. That is, when forming conductive patterns of Cu or by performing a plating process, it should be readily understood that a process of forming a seed layer may proceed followed by a chemical mechanical polishing (CMP) and other processes, if any. Cu may be formed by a plating method, as opposed to a deposition method. Furthermore, Cu may be patterned by a CMP method, as opposed to an etching process. Therefore, Cu as a material for forming conductive patterns is distinguished from other metals that tolerate a deposition or etching process.

According to an embodiment of the present invention, no insulation layer is formed between the semiconductor layer 100 and the TSV 150. Instead, a diode 160 (hereinafter, referred to as a reverse diode or backward diode) is formed between the semiconductor substrate 100 and the TSV 150 to block a current flow therebetween. The structure equivalent to a reverse diode 160 may be formed without requiring a separate manufacturing step by controlling the one or more bias voltages applied to the semiconductor substrate 100 and the TSV 150. Since the semiconductor substrate 100 is formed of a silicon material and the TSV 150 is formed of a metallic material, the reverse diode 160 may be of a Schottky diode-type.

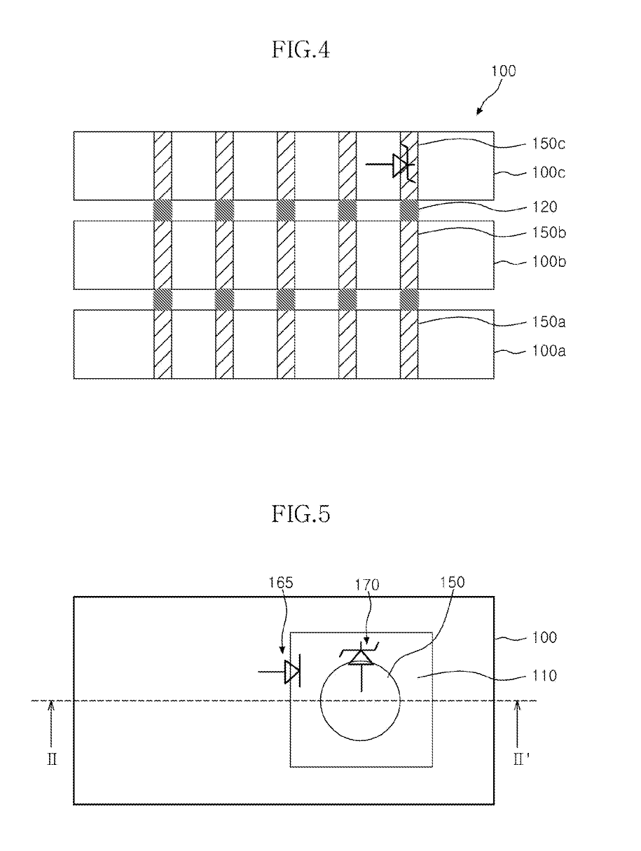

When it is assumed that the semiconductor substrate 100 is a p-type silicon substrate, the backward Schottky diode 160 according to an embodiment controls a voltage applied to the semiconductor substrate 100 (hereinafter, referred to as a first voltage V1) such that the first voltage V1 becomes slightly lower than a voltage applied to the TSV 150 (hereinafter, referred to as a second voltage V2). For example, when the first voltage V1 is Vss voltage, the second voltage V2 may be set to a voltage higher than the Vss voltage. Referring to FIG. 3, the negative (−) swing level A of the Vss voltage may be supplied as the first voltage V1, and the positive (+) swing level B of the Vss voltage may be supplied as the second voltage V2.

A reverse Schottky diode has a lower breakdown voltage than a PN diode. Therefore, it is desirable that the difference between the first and second voltages V1 and V2 is small.

As a result of forming the structure equivalent to a reverse Schottky diode 160 between the TSV 150 and the semiconductor substrate 100, a backward bias (reverse bias) higher than the breakdown voltage is present. Accordingly, there would be no electric current flow between the semiconductor substrate 100 and the TSV 150.

FIG. 4 is a cross-sectional view of a multi-chip package 100 including semiconductor substrates having the TSV formed in such a manner as described according to an embodiment of the present invention.

Referring to FIG. 4, semiconductor chips 100a, 100b, and 100c including TSVs 150a, 150b, 150c, respectively, are stacked in such a manner that TSVs 150a, 150b, and 150c are aligned to receive the same respective signals. Each TSV 150a, 150b, 150c is formed to directly contact its respective substrate.

External coupling terminals 120 such as bumps are formed between the semiconductor chips 100a, 100b, 100c so as to electrically connect the TSVs 150a, 150b, 150c of one stacked semiconductor chip to the corresponding TSVs 150a, 150b, 150c of another stacked chip and transfer signals through the coupled TSVs respectively.

According to an embodiment, a semiconductor chip having a interface member such as a TSV but without requiring an insulation layer between the TSV and the substrate can be formed to have a bias applied between the interface member and the substrate so as to form a reverse diode for preventing electrical current flow therebetween. Accordingly, although an insulation layer is not formed between the semiconductor chip and the interface member, a potential barrier between silicon and metal may substantially prevent electron transfer between the semiconductor chip and the interface member. Therefore, the generation of parasitic capacitance between the semiconductor chip and the interface member may be prevented to thereby improve the signal transfer speed.

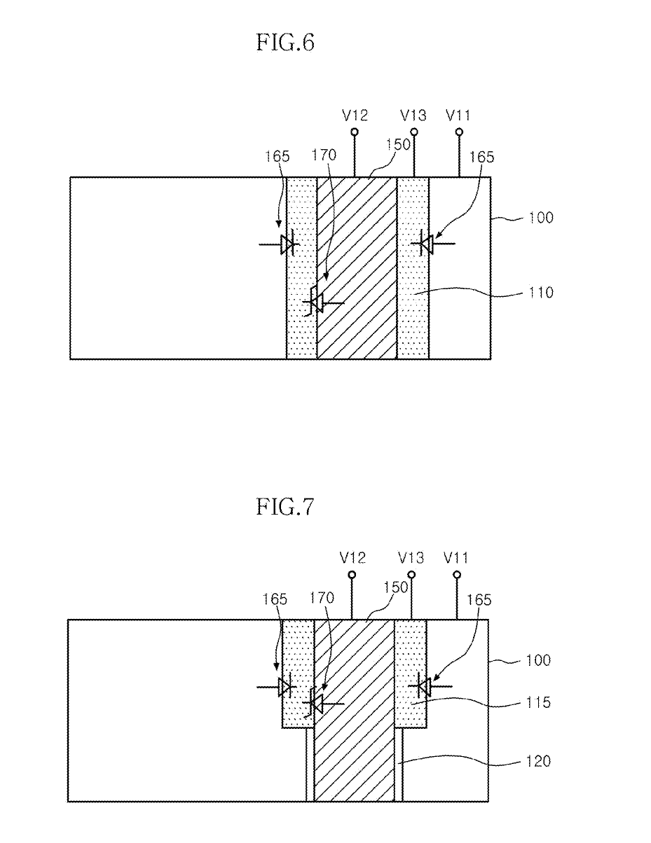

Referring to FIGS. 5 and 6, the TSV 150 may be surrounded by a well 110. When the semiconductor substrate 100 is a P-type semiconductor substrate, the well 110 may be an N well. Between the TSV 150 and the well 110 and between the well 110 and the semiconductor substrate 100, no insulation layer exists.

In such a case, while a predetermined bias is applied to form a reverse PN diode 165 between the semiconductor substrate 100 and the well 110, a bias is applied to form a forward Schottky diode 170 between the TSV 150 and the well 110.

That is, referring to FIG. 6, a first voltage V11 may be applied to the semiconductor substrate 100, a second voltage V12 higher than the first voltage V11 may be applied to the TSV 150, and a third voltage V13 higher than the second voltage V12 may be applied to the well 110. For example, VBB voltage may be used as the first voltage V11, VSS voltage may be used as the second voltage V12, and VDD or VPP voltage may be used as the third voltage V13.

When the first to third voltages V11, V12, to V13 are applied to the semiconductor substrate 100, the TSV 150, and the well 110, respectively, the reverse PN diode 165 is formed between the semiconductor substrate 100 and the well 110, and the forward Schottky diode 170 is formed between the well 110 and the TSV 150 as described above.

A reverse PN diode 165 is considered to be more stable against leakage currents than a forward Schottky diode 170. Therefore, when the TSV 150 is formed in a well 110, it may prevent the generation of current in a more stable manner.

The ion implantation and diffusion processes may take a long processing time when they are performed to form the well 110 to the total thickness of the semiconductor substrate 100. Then, referring to FIG. 7, a well 115 may be formed to a predetermined depth in the substrate 100 to surround an upper portion of the TSV 150, and an insulation layer 120 may be formed in the substrate 100 under the well 115 between the semiconductor substrate 100 and the lower portion of the TSV 150. Since the well 115 is formed to a predetermined depth in the substrate 100, the lesser area of the insulation layer 120 is needed than the surface area needed to insulate the entire depth of the TSV 150. Then, the parasitic capacitance, if any, between the semiconductor substrate 100 and the TSV 150 would be at a minimal level that would not influence the speed, such that the signal transfer characteristics would be improved. The first voltage V11, the second voltage V12, and the third voltage V13 are applied to the semiconductor substrate 100, the well 115, and the TSV 150, respectively, similar to the above-described embodiment.

According to an embodiment, in order to provide insulation between the semiconductor substrate formed of silicon and the interface member such as TSV, the biasing condition can be controlled to form the structure equivalent to a backward diode, instead of forming an insulation layer.

Accordingly, although there is a physical contact between the semiconductor chip and the interface member, electron transfer between them is blocked by the silicon-metal barrier, and thus current does not flow.

Therefore, since the parasitic capacitance between the semiconductor chip and the interface member is not generated, it is possible to significantly improve the signal transfer speed between multilayered chips composing a multi-chip package as well as inside the chips.

While certain embodiments have been described above, it will be understood to those skilled in the art that the embodiments described are by way of example only. Accordingly, the semiconductor chip and the multi-chip package described herein should not be limited based on the described embodiments. Rather, the semiconductor chip and the multi-chip package described herein should only be limited in light of the claims that follow when taken in conjunction with the above description and accompanying drawings.

What is claimed is:

1. A semiconductor chip comprising:
a semiconductor substrate at a first voltage level;
an interface member at a second voltage level formed through the semiconductor substrate,
wherein electric current flow between the semiconductor substrate and the interface member is substantially prevented by controlling the first and second voltage levels.

2. The semiconductor chip according to claim 1, wherein the semiconductor substrate and the interface member are directly in contact with each other.

3. The semiconductor chip according to claim 1, wherein the semiconductor substrate comprises a silicon of a first conductive type, and the interface member comprises a through-silicon via (TSV) comprising a metallic material.

4. The semiconductor chip according to claim 3, wherein the first and second voltage levels are controlled to create a condition of a reverse Schottky diode between the semiconductor substrate and the TSV.

5. The semiconductor chip according to claim 4, wherein the first voltage level is lower than the second voltage level.

6. The semiconductor chip according to claim 5, wherein the first voltage level corresponds to a negative (−) swing voltage band of a Vss voltage, and the level of the second voltage corresponds to a positive (+) swing voltage band of the Vss voltage.

7. The semiconductor chip according to claim 3, further comprising a well at a third voltage level surrounding the TSV in the semiconductor substrate.

8. The semiconductor chip according to claim 7, wherein the well is of an opposite conductive type than the first conductive type of the semiconductor substrate.

9. The semiconductor chip according to claim 8, wherein the first, second, and third voltage levels are controlled to form a structure equivalent to a reverse diode between the semiconductor substrate and the well and a structure equivalent to a forward diode between the well and the TSV.

10. The semiconductor chip according to claim 8, wherein the third voltage level is higher than the second voltage level, which is higher than the first voltage level.

11. The semiconductor chip according to claim 10, wherein the first voltage comprises VBB voltage, the second voltage comprises Vss voltage, and the third voltage comprises a VDD or VPP voltage.

12. The semiconductor chip according to claim 10, wherein the well is formed to surround only a predetermined depth of the TSV, and an insulation layer is formed outside the TSV where the well is not formed.

13. A multi-chip package comprising:
a plurality of stacked semiconductor chips, each semiconductor chip comprising an interface member at a second voltage level formed in a semiconductor substrate at a first voltage level, wherein the interface member is directly in contact with the semiconductor substrate;
and
an external coupling terminal provided to electrically couple the interface members of two stacked semiconductor chips.

14. The multi-chip package according to claim 13, wherein the first and second voltage levels applied to the semiconductor substrate and the interface member form a potential barrier preventing electron transfer.

15. The multi-chip package according to claim 14, wherein the first voltage is lower than the second voltage.

16. A multi-chip package comprising:
a plurality of stacked semiconductor chips, each semiconductor chip comprising an interface member formed in a well, which is formed in a semiconductor substrate, wherein the well and the semiconductor are of opposite conductive type, and wherein the semiconductor substrate is at a first voltage level, the interface member is at a second voltage level, and the well is at a third voltage level; and
an external coupling terminal provided to electrically couple the interface members of two stacked semiconductor chips.

17. The multi-chip package according to claim 16, where the first and third voltages are applied to form a reverse diode condition between the semiconductor chip and the well, and the second voltage and the third voltage are applied to form a forward diode condition between the interface member and the well.

18. The multi-chip package according to claim 17, wherein the second voltage is higher than the first voltage, and the third voltage is higher than the second voltage.

19. The multi-chip package according to claim 18, wherein the well is formed to surround a predetermined depth of the interface member, and an insulation layer is formed outside the interface member where the well is not formed.

20. A semiconductor chip comprising:
a semiconductor substrate at a first voltage level;
a TSV (through silicon via) at a second voltage level formed through the semiconductor substrate, wherein the TSV is contacted with the semiconductor substrate; and
a reverse diode parasitically formed between the semiconductor substrate and the TSV for preventing by controlling the first and second voltage levels.
